(19) United States
(12) Patent Application Publication
(10) Pub. No.: US 2018/0285252 A1
(43) Pub. Date: Oct. 4, 2018

(54) OPTIMIZED MEMORY ACCESS BANDWIDTH DEVICES, SYSTEMS, AND METHODS FOR PROCESSING LOW SPATIAL LOCALITY DATA

(71) Applicant: Intel Corporation, Santa Clara, CA (US)

(72) Inventors: Kon-Woo Kwon, Hillsboro, OR (US); Vivek Kozhikkottu, Hillsboro, OR (US); Sang Phill Park, Hillsboro, OR (US); Ankit More, Hillsboro, OR (US); William P. Griffin, Hillsboro, OR (US); Robert Pawlowski, Portland, OR (US); Jason M. Howard, Portland, OR (US); Joshua B. Fryman, Corvallis, OR (US)

(73) Assignee: Intel Corporation, Santa Clara, CA (US)

(21) Appl. No.: 15/477,072

(22) Filed: Apr. 1, 2017

(51) Int. Cl. G06F 12/02; G06F 12/0802; G06F 12/0846; G11C 7/10; G06F 12/06

(52) U.S. Cl. CPC G06F 12/023; G06F 12/0802; G06F 2212/62; G11C 7/1072; G06F 12/0638; G06F 12/0848

(57) ABSTRACT

Optimized memory access bandwidth devices, systems, and methods for processing low spatial locality data are disclosed and described. A system memory is divided into a plurality of memory subsections, where each memory subsection is communicatively coupled to an independent memory channel to a memory controller. Memory access requests from a processor are thereby sent by the memory controller to only the appropriate memory subsection.

### BACKGROUND

Various computation systems, such as machine learning, graph analytics, and the like, inherently access data in random patterns. In such processing systems, the spatial locality of data can be low due to the fact that random nature of data access precludes the storage of data in proximity according to relatedness. In traditional computing systems, the access of one portion of data can be predictive of subsequent portions of data that will likely be accessed. As such, data is stored in physical locations according to such predictive relatedness, or in other words, stored according to spatial locality. The concept of spatial locality posits that data should be stored in physical locations according to such predictive data access patterns, according to the actual physical proximity of the data, the physical locations from which data and the related data are retrieved as a result of a memory access request, or both. By storing such related data in locations that result in its retrieval along with the requested data in a memory access request, the related data can be stored in cache, which greatly reduces memory access latency on subsequent requests. For example, in a traditional system having 64 Byte data lines of multiple 8 Byte words, a read request for an 8 Byte word results in the retrieval of the entire 64 Byte data line. Storing related data in physical memory locations that correspond to the other 56 Bytes of the data line causes such data to be retrieved along with the requested data, which can be cached to await subsequent accesses.

### BRIEF DESCRIPTION OF THE DRAWINGS

FIG. 1 illustrates a diagram of a traditional dual in-line memory module (DIMM);

FIG. 2 illustrates a diagram of a traditional dual in-line memory module (DIMM) and memory controller;

FIG. 3A illustrates a diagram of a memory subsystem in accordance with an example embodiment;

FIG. 3B illustrates a diagram of a memory subsystem in accordance with an example embodiment;

FIG. 4 illustrates a diagram of a memory subsystem in accordance with an example embodiment;

FIG. 5A shows a top-down view of a DIMM in a DIMM connector in accordance with an example embodiment;

FIG. 5B shows a top-down view of a DIMM in a DIMM connector in accordance with an example embodiment;

FIG. 6 shows a side view of a DIMM in accordance with an example embodiment;

FIG. 7 shows a side view of a DIMM with associated memory controllers in accordance with an example embodiment;

FIG. 8 illustrates a diagram of a processor package system in accordance with an example embodiment;

FIG. 9 shows a perspective view of stacked memory in accordance with an example embodiment;

FIG. 10 shows a diagram circuitry functions in accordance with an example embodiment;

FIG. 11 shows a diagram circuitry functions in accordance with an example embodiment;

FIG. 12A shows a diagram of a method in accordance with an example embodiment;

FIG. 12B shows a diagram of a method in accordance with an example embodiment;

FIG. 12C shows a diagram of a method in accordance with an example embodiment; and

FIG. 13 illustrates a block diagram of a computing system in accordance with an example embodiment.

### DESCRIPTION OF EMBODIMENTS

Although the following detailed description contains many specifics for the purpose of illustration, a person of ordinary skill in the art will appreciate that many variations and alterations to the following details can be made and are considered included herein. Accordingly, the following embodiments are set forth without any loss of generality to, and without imposing limitations upon, any claims set forth. It is also to be understood that the terminology used herein is for describing particular embodiments only, and is not intended to be limiting. Unless defined otherwise, all technical and scientific terms used herein have the same meaning as commonly understood by one of ordinary skill in the art to which this disclosure belongs. Also, the same reference numerals in appearing in different drawings represent the same element. Numbers provided in flow charts and processes are provided for clarity in illustrating steps and operations and do not necessarily indicate a particular order or sequence.

Furthermore, the described features, structures, or characteristics can be combined in any suitable manner in one or more embodiments. In the following description, numerous specific details are provided, such as examples of layouts, distances, network examples, etc., to provide a thorough understanding of various embodiments. One skilled in the relevant art will recognize, however, that such detailed embodiments do not limit the overall concepts articulated herein, but are merely representative thereof. One skilled in the relevant art will also recognize that the technology can be practiced without one or more of the specific details, or with other methods, components, layouts, etc. In other instances, well-known structures, materials, or operations may not be shown or described in detail to avoid obscuring aspects of the disclosure.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open-ended term in this written description, like “comprising” or “including,” it is understood that direct support should be afforded also to “consisting essentially of” language as well as “consisting of” language as if stated explicitly and vice versa.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of phrases including “an example” or “an embodiment” in various places throughout this specification are not necessarily all referring to the same example or embodiment.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

As used herein, comparative terms such as “increased,” “decreased,” “better,” “worse,” “higher,” “lower,” “enhanced,” and the like refer to a property of a device, component, or activity that is measurably different from other devices, components, or activities in a surrounding or adjacent area, in a single device or in multiple comparable devices, in a group or class, in multiple groups or classes, or as compared to the known state of the art. For example, a data region that has an “increased” risk of corruption can refer to a region of a memory device which is more likely to have write errors to it than other regions in the same memory device. A number of factors can cause such increased risk, including location, fabrication process, number of program pulses applied to the region, etc.

An initial overview of embodiments is provided below and specific embodiments are then described in further detail. This initial summary is intended to aid readers in understanding the disclosure more quickly, but is not intended to identify key or essential technological features, nor is it intended to limit the scope of the claimed subject matter.

Many processing applications benefit from a fine-grained memory access limitation due to, among other things, inherent random data access patterns. These access patterns tend to result in a low incidence of, or even an absence of, spatial locality of related data. In traditional computing systems, a memory access request from system memory results in the retrieval of data in excess of the requested data, due to system architecture constraints imposed historically in memory system design, among other things. Data is often organized in such systems so that the data stored in these “excess data regions” of memory is related to the requested data, and is thus more likely to be subsequently requested by a host process compared to other data in memory. This organization of spatial-relatedness is known as “spatial locality.” In other words, data is organized in memory so that data stored physically near the requested data is more likely to be subsequently requested compared to data stored physically further away. This excess data is generally referred to as “prefetch data,” which is retrieved with the requested data and placed into cache, where it can be accessed much more quickly compared to accessing from system memory. In processing systems utilizing inherently random data access patterns, however, data organized according to relatedness has a very low spatial locality due to the random nature of the data access. In these situations, the likelihood that such data, prefetched based merely on physical proximity to requested data, will be subsequently requested is no higher than any other data in system memory.

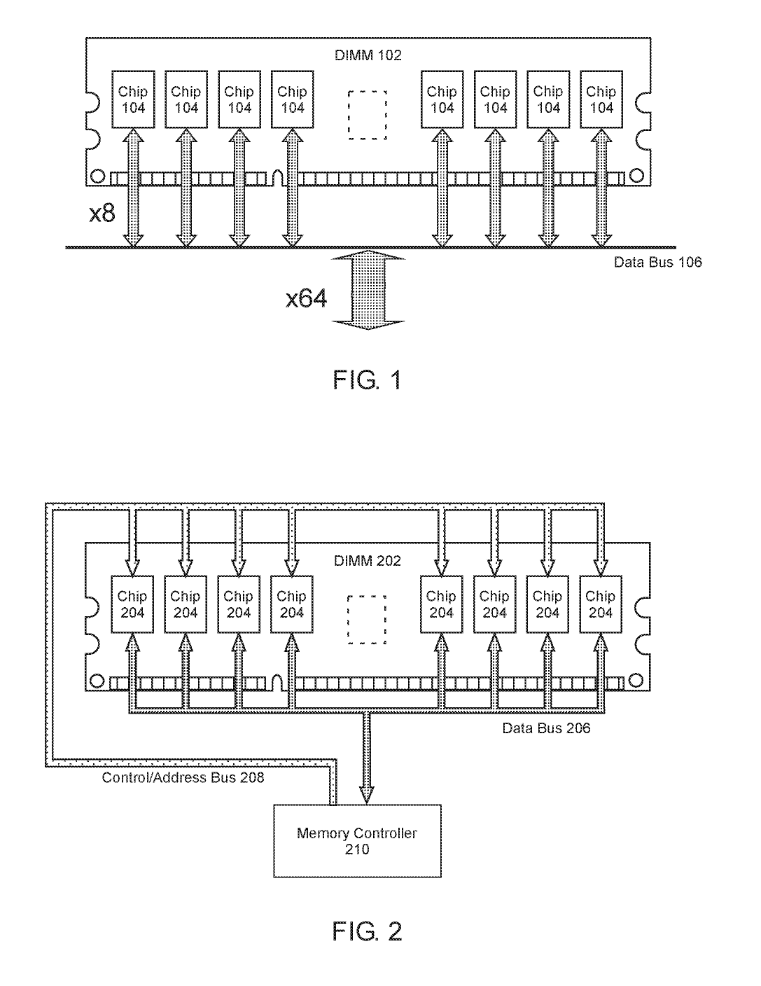

In general computer systems, memory access requests retrieve an entire data line that includes multiple data words. As one example, FIG. 1 shows a dual in-line memory module (DIMM) 102 having a rank of eight dynamic random-access memory (DRAM) chips 104 connected to a common data bus 106. Because the rank shares the same chip select and command bus, a single memory access command to read a single data word located in a single memory chip will activate all eight memory chips 104, and will thus retrieve eight words of data for each read command. Assuming x8 DRAM memory chips with a burst length of eight, each word is 8-Bytes (i.e., the memory access granularity), and thus the data line size is 64-Bytes. Words in the data line that are not targeted by the data request are sent to the system cache as prefetch data according to the principle of spatial locality.

In a system where the spatial locality of data is low due to, for example, random data access patterns, a memory access request that retrieves prefetch data having little to no caching benefit is a waste of resources, such as, for example, activation energy, input/output (I/O) energy, bandwidth, and the like. More specifically, if the memory access granularity is 8-Bytes, for example, a memory access request for an 8-Byte data chunk also retrieves 56-Bytes of prefetch data. Regarding some of the specifics of resource usage, activation energy is dissipated when, for the example of DRAM memory, a row of data is transferred from the memory array into the sense amplifiers of a row buffer. I/O energy is associated with the power consumed to operate the data bus over the duration of the data transmission. Hence I/O energy is proportional to the total amount of data transferred per access, which is 64-Bytes in the case of FIG. 1. This I/O energy consumption is about eight times higher than the minimum energy required for an 8-Byte memory access. Also, the actual bandwidth for random 8-Byte accesses is ⅛ of the peak bandwidth, because 56-Bytes of prefetch data from the transferred 64-Bytes is unused and discarded. It is thus clear that a traditional memory having a prefetch architecture is suboptimal for systems having data stored with low spatial locality.

To address these high energy and bandwidth overheads, and to increase the overall performance of systems where the spatial locality of data is inherently low to nonexistent, the present disclosure provides memory technologies that have memory access granularities of the minimum potential size of a memory access request. One example of such a memory system retrieves only the requested data in response to a memory access read request. Similarly, in response to a memory access write request, such a system only writes the requested data to memory, without needing to utilize the traditional read-modify-write protocol to avoid overwriting unrelated data in the other DRAM chips in the rank when writing the data line back to the DRAM. Thus, in an example of a DRAM DIMM having eight x8 DRAM chips in a rank and a burst length of eight, a memory access request for an 8-Byte word activates only the DRAM chip storing the requested 8-Byte word of data, and only retrieves the data from that DRAM chip. Similarly, a memory access request to write the 8-Byte word of data would activate only the DRAM chip storing the word of data. As a general example of the currently disclosed technology, the traditional wide I/O channel (64-Byte) to and from memory is separated into multiple narrow I/O channels (8-Byte) (i.e. memory channels). Each narrow memory channel can be optimized for any useful bandwidth, which can depend on the memory architecture, the granularity of associated processors, and the like. In one example, the word size of a memory can be used to establish the memory access granularity of the associated memory channels, such that a word of data is retrieved in response to a single activation command over a single memory channel, and with no prefetch data retrieved. Compared to the example of the DRAM DIMM shown in FIG. 1, the activation and I/O energies are eight times lower, and the bandwidth is eight times higher.

FIG. 2 shows another example of a DRAM DIMM 202, having a rank of eight memory chips 204 connected to a common data bus 206, and to a common control/address bus 208. The memory chips 204 are communicatively coupled to a memory controller 210 via the common data bus 206 and the common control/address bus 208. As a general example of the functionality of these common buses, in response to receiving a memory access request from a host, the memory controller 210 generates memory commands to process the memory access request, and activates a common chip select via the common control/address bus 206, which activates all of the memory chips 204 in the rank. In the case of a read request, for example, a word of data corresponding to the memory access request is retrieved from the memory chip storing the word, along with a word of excess data from the same row location in each of the other seven memory chips. The word of requested data, along with the seven words of excess data, are sent to the memory controller over the common data bus 206. The memory controller 210 then sends the word of requested data to the host from which the memory access request was received, and sends the seven words of excess data to the system cache. Thus, because the all of the memory chips in the rank share the same chip select and command bus, a single memory access command in this DRAM example will activate all eight memory chips 104, and will thus retrieve of data from each memory chip.

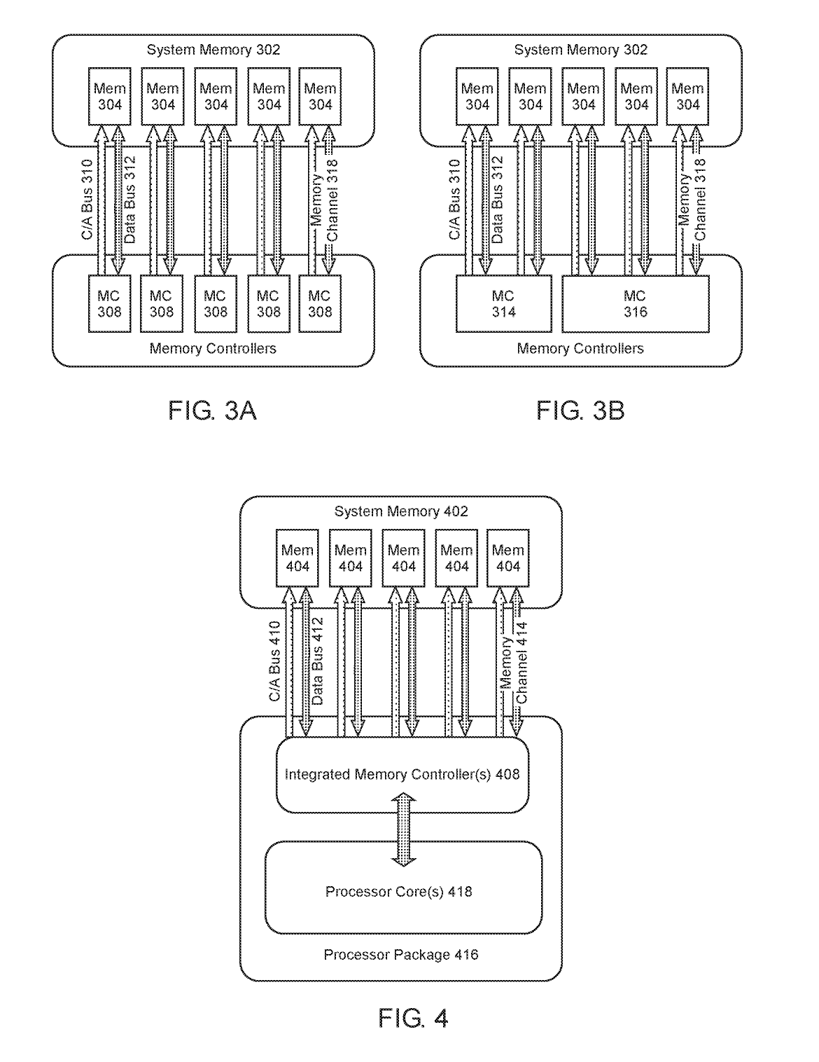

By separating the traditional wide I/O channel into multiple independent narrow-width channels, the performance of systems and applications utilizing random data access patterns can be greatly increased. One example is shown in FIG. 3A, which includes a system memory 302 that is divided into a plurality of memory subsections 304, and at least one memory controller 308. The example shown in FIG. 3A illustrates a plurality of memory controllers 308, with each memory subsection 304 having a corresponding memory controller 308. Each memory subsection 304 is communicatively coupled to a memory controller 308 through an independent (or dedicated) command bus (i.e. command/address bus or control/address bus) 310 and an independent (or dedicated) data bus 312. This independent communication pathway to a given memory subsection can be referred to herein as a “memory channel” 318. Thus, each independent memory channel 318 provides a dedicated communication pathway between a memory controller 308 and a memory subsection 304. The memory controller can communicate with the associated memory subsection through a system memory interface (not shown). The term “system memory interface” refers to any type of interface where a system memory or a memory subsection can be coupled to one or more memory channels. Nonlimiting examples can include connectors, sockets, pins, soldered connections, semiconductive connections, vias, pads, and the like. Additionally, an “independent” memory channel, for example, refers to a memory channel that is independent and separate from other memory channels, and as such, provides data and command communication only between a memory controller and the associated memory segment. Similarly, a “dedicated” command bus, for example, refers to a command bus that is solely dedicated to communication within the associated independent memory channel.

In some examples, a memory controller 308 can be a dedicated memory controller for only one memory channel 318, and thus will control data and command operations only with the memory subsection 304 associated with that memory channel 318. In other examples, a memory controller can control data and command operations over multiple independent memory channels for multiple memory subsections. FIG. 3B shows one example of such multi-channel memory controllers. In this example, memory controller 314 controls data and command operations for two memory subsections 304 over two independent memory channels 318. Memory controller 316 controls data and command operations for three memory subsections 304 over three independent memory channels 318. A memory controller can thus control any number of memory subsections through the associated independent memory channels.

The data access granularity of each independent memory channel can vary depending on the architecture of the comping system, the host processor(s), the type of memory and memory configuration, and the like. In one example, however, the data access granularity of each independent memory channel is a product of the data bus bit-width and the data bus burst length. In other words, in the case of an example DRAM memory segment having 8 data lines in the dedicated data bus, the bit width would be 8 bits. If the burst length is set to 1, then each read command would retrieve 1 bit of data from each data line, for a total of 1 Byte (8 bits) of data. In this case, the data access granularity would be 1 Byte. If the burst length was set to 8, then each read command would retrieve 8 bits (or one Byte) of data from each data line, for a total of 8 Bytes (64 bits). In this case, the data access granularity is 8 Bytes. While any value is considered to be within the present scope, in one example the data access granularity of each independent memory channel is a multiple of 8 Bytes. In another example, the data access granularity of each independent memory channel is 8 Bytes.

One benefit to a memory architecture that utilizes such narrow independent memory channels for dedicated data and command communications with individual memory subsections relates to memory subsection failure, and the effects of such failure on the memory subsystem as a whole. Because traditional memory, such as a DRAM DIMM, for example, retrieves data from all DRAM chips in a rank for every memory read access, failure of a single DRAM chip, or portion of a DRAM chip, causes the entire DRAM DIMM to fail. Such a DRAM chip failure in a memory subsection, including partial failures or other efficiency reductions, having dedicated communication with a memory controller over an independent memory channel according to the presently disclosed technology, however, does not affect the remaining memory subsections or the associated independent memory channels. In such cases, the affected memory subsection can be disabled independently from the remaining memory, thus allowing continued use. As such, each independent memory channel can be configured to be disabled independently from each of the other memory channels. This can be accomplished by any known technique, such as, for example, removing or otherwise invalidating the address space of the affected memory subsection from the system memory map, memory management unit and/or memory controller address tables, disabling a dedicated memory controller, and the like. Such memory subsection failures, partial failures, or other undesirable effects, can occur over time during use, or they can be a result of the manufacturing process, which are often discovered during quality control testing. In quality control testing, such failures are often discovered only after the product has been fully manufactured. Traditionally, the entire memory device, including the functional memory subsections, is discarded. In a memory device having independent memory channel communication to each memory subsection, however, a failed memory subsection can be independently disabled, and the memory device can be used. In some cases, a memory device having fewer memory subsections than intended can be utilized as described. In other case, a memory device can be manufactured with one or more extra memory subsections. In the event that a memory subsection fails, either during manufacture or during use, the disabling of a memory subsection would still provide a memory device with at least the intended number of memory subsections.

Various configurations are possible for the memory controller(s), the memory, the memory subsections, the memory subsystems, and the like, and any such configuration is considered to be within the present scope. Depending on the memory system architecture, memory controllers can reside away from host processor(s), such as in a controller hub or other external memory controller location, or on a memory module such as a DIMM. In some examples, the memory controllers can be integrated in a common package with the host processor(s). FIG. 4, for example, shows a memory subsystem having a system memory 402 that is divided into a plurality of memory subsections 404, with each memory subsection 404 having an independent memory channel 414 of an independent command bus 410 and an independent data bus 412. In this example, memory controller is an integrated memory controller 408 that resides on a processor package 416 with one or more processors or processor cores 418. In one example, the integrated memory controller 408 can be a single integrated memory controller that communicates with each memory subsection 404 independently over each dedicated memory channel 412. In another example, the integrated memory controller 408 can be a plurality of integrated memory controllers, each communicating independently with a memory subsection 404 over the memory subsection's dedicated memory channel 412.

As such, a memory controller is communicatively coupled to a memory segment via an independent memory channel comprising a data bus and a command bus. Memory access requests are sent to the memory controller from a host, such as a processor or processor core, and the memory controller generates the appropriate memory commands, which are sent through the command bus of the independent memory channel to the associated memory segment. If the memory access request is a read request, the read data is retrieved from the memory segment, and sent to the memory controller over the data bus. The memory controller then completes the memory access request by sending the read data to the host. If, on the other hand, the memory access request is for a write request, the memory controller also receives data to be written to memory. The memory controller, in addition to sending the memory commands for the write request over the command bus, sends the write data to the memory segment over the data bus. Because the write data includes only data to be written to a single memory segment, a read-modify-write procedure is not necessary to protect other memory segments from overwrites. In some cases, memory access requests, incoming write data, outgoing read data, and the like, can be queued in corresponding buffers to improve efficiency. It is noted that the functions of a memory controller can be performed in various sequential orders, and can depend on a particular memory controller or memory system architecture. Additionally, the various functions can be implemented as discrete units of circuitry, logic, code, or the like, or one or more these functions can be commonly implemented or integrated in a unit of circuitry, logic, code, or the like.

The system memory can include any type of volatile or nonvolatile memory, and is not considered to be limiting. Volatile memory, for example, is a storage medium that requires power to maintain the state of data stored by the medium. Nonlimiting examples of volatile memory can include random access memory (RAM), such as static random access memory (SRAM), dynamic random-access memory (DRAM), synchronous dynamic random access memory (SDRAM), and the like, including combinations thereof. SDRAM memory can include any variant thereof, such as single data rate SDRAM (SDR DRAM), double data rate (DDR) SDRAM, including DDR, DDR2, DDR3, DDR4, DDR5, and so on, described collectively as DDRx, and low power DDR (LPDDR) SDRAM, including LPDDR, LPDDR2, LPDDR3, LPDDR4, and so on, described collectively as LPDDRx. In some examples, DRAM complies with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209B for LPDDR SDRAM, JESD209-2F for LPDDR2 SDRAM, JESD209-3C for LPDDR3 SDRAM, and JESD209-4A for LPDDR4 SDRAM (these standards are available at www.jedec.org; DDR5 SDRAM is forthcoming). Such standards (and similar standards) may be referred to as DDR-based or LPDDR-based standards, and communication interfaces that implement such standards may be referred to as DDR-based or LPDDR-based interfaces. In one specific example, the system memory can be DRAM. In another specific example, the system memory can be DDRx SDRAM. In yet another specific aspect, the system memory can be LPDDRx SDRAM.

Nonvolatile memory (NVM) is a persistent storage medium, or in other words, a storage medium that does not require power to maintain the state of data stored therein. Nonlimiting examples of NVM can include planar or three-dimensional (3D) NAND flash memory, NOR flash memory, cross point array memory, including 3D cross point memory, phase change memory (PCM), such as chalcogenide PCM, non-volatile dual in-line memory module (NVDIMM), ferroelectric memory (FeRAM), silicon-oxide-nitride-oxide-silicon (SONOS) memory, polymer memory (e.g., ferroelectric polymer memory), ferroelectric transistor random access memory (Fe-TRAM), spin transfer torque (STT) memory, nanowire memory, electrically erasable programmable read-only memory (EEPROM), magnetoresistive random-access memory (MRAM), write in place non-volatile MRAM (NVMRAM), nanotube RAM (NRAM), and the like, including combinations thereof. In some examples, non-volatile memory can comply with one or more standards promulgated by the Joint Electron Device Engineering Council (JEDEC), such as JESD218, JESD219, JESD220-1, JESD223B, JESD223-1, or other suitable standard (the JEDEC standards cited herein are available at www.jedec.org). In one specific example, the system memory can be 3D cross point memory. In another specific example, the system memory can be STT memory.

The physical nature of the memory segments can vary, depending on the type and architectural organization of the system memory. In some examples, a memory segment can be a physically delineated portion of the system memory, such as, for example, a DRAM chip. As such, a DRAM DIMM having eight DRAM chips on either side has 16 memory segments, one for each DRAM chip. It is noted however, that in some cases memory segmentation may not coincide with a physical delineation within the system memory. In such cases, memory segments may be defined merely by the memory channel inputs to various regions of system memory.

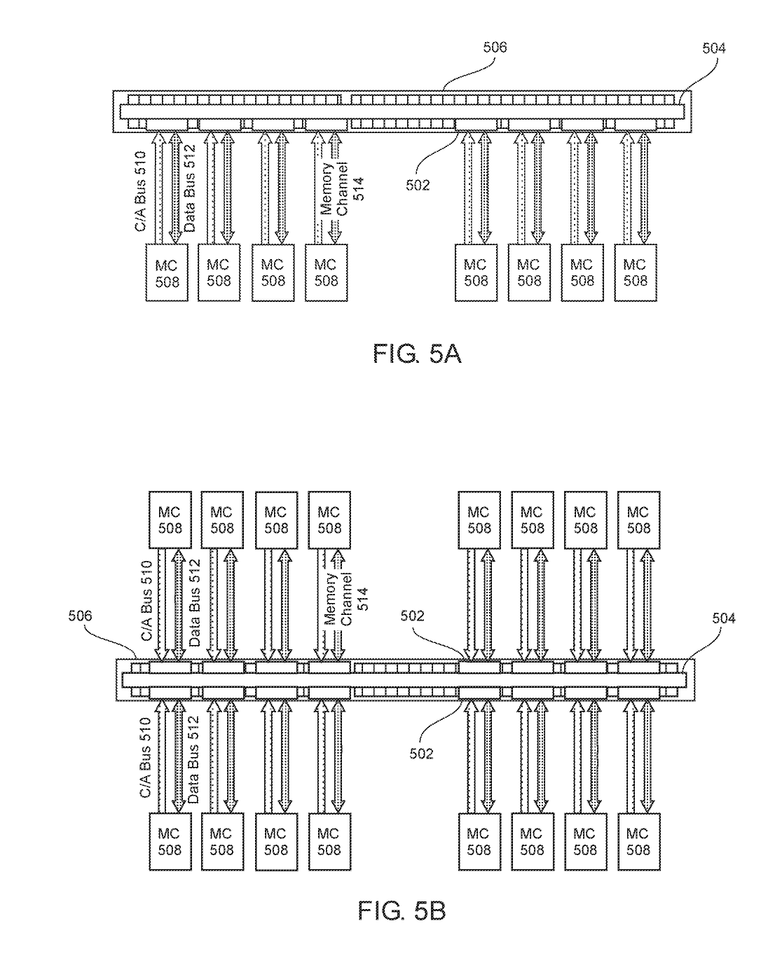

In one example embodiment, as is shown in FIG. 5A, the memory segments 502 are individual memory chips coupled to a memory card, such as a DIMM 504. The DIMM 504 is shown coupled to a DIMM connector 506, with the memory segments 502 mounted on one side. It is noted that, while much of the following description refers to the structure supporting the memory segments as a DIMM, such is merely for convenience, and it should be understood that the present scope encompasses any support, memory card, circuit board, or memory module architecture capable of supporting memory segments. Each memory segment 502 is communicatively coupled to an independent memory channel 514 including an independent command bus 510 and an independent data bus 512. As has been described, the system memory can be any type of volatile or NVM. In one example, the system memory can be DRAM, such as, for example, DDRx SDRAM. In another example, the system memory can be 3D cross point memory. In yet another example, the system memory can be STT memory. Additionally, in some cases a DIMM can be a hybrid DIMM, and thus include both volatile memory and nonvolatile memory. One nonlimiting example of a hybrid DIMM can include DDRx SDRAM and 3D cross point memory types. In some examples, hybrid DIMMs can comply with a standard promulgated by JEDEC. For example, a hybrid DIMM based on the DDR4 NVDIMM-N DESIGN STANDARD (Revision 1.0). This standard defines the electrical and mechanical requirements for 288-pin, 1.2 Volt (VDD), DDR, Synchronous SDRAM Nonvolatile DIMM, with NAND flash backup (DDR4 NVDIMM-N). DDR4 NVDIMM-N is a hybrid memory module with a DDR4 DIMM interface comprising DRAM that is made nonvolatile through the use of NAND Flash. NVDIMM-N modules adhere to the Byte Addressable Energy Backed Interface Standard, JESD245, which provides detailed logical behavior, interface, and register definitions. These DDR4 NVDIMM-N modules can be used for main memory or storage memory.

FIG. 5B shows a similar configuration, with a DIMM 504 having memory segments 502 mounted on both sides. Each memory segment 502 can be communicatively coupled to a dedicated memory controller 508 through an independent memory channel 514 as shown, or one or more memory controllers can control multiple independent memory channels (not shown). For example, a single memory controller can control at least a memory segment on one side of the DIMM and the memory segment directly on the opposite side of the DIMM. The memory controller can interact with the two opposite memory segments through two independent memory channels, or the memory controller can interact with the two opposite memory segments by multiplexing over the same physical channel.

In some examples, a DIMM can be configured to support various types of memory, in some cases as has been described above. As such, a DIMM can be configured to match certain of the specification details, that do not conflict with the presently disclosed technology, for the particular memory-type that is being supported thereon. For example, a DIMM supporting xDDR SDRAM can be configured according to the JEDEC specifications for the specific xDDR memory being used. Also, DIMMs can comply with a one or more DIMM standards promulgated by JEDEC. One example can be a DIMM based on the Registered DIMM Design Specification, that defines the electrical and mechanical requirements for 288-pin, 1.2 Volt (VDD), Registered, Double Data Rate, Synchronous DRAM Dual In-Line Memory Modules (DDR4 SDRAM RDIMMs). In another example, a DIMM can be based on the DDR4 SDRAM Unbuffered DIMM Design Specification that defines the electrical and mechanical requirements for the 288-pin, 1.2 Volt (VDD), Unbuffered, Double Data Rate, Synchronous DRAM Dual In-Line Memory Modules (DDR4 SDRAM UDIMMs). In yet another example, a DIMM can be based on the DDR4 SDRAM SO-DIMM Design Specification, which defines the electrical and mechanical requirements for 260 pin, 1.2 V (VDD), Small Outline, Double Data Rate, Synchronous DRAM Dual In-Line Memory Modules (DDR4 SDRAM SODIMMs).

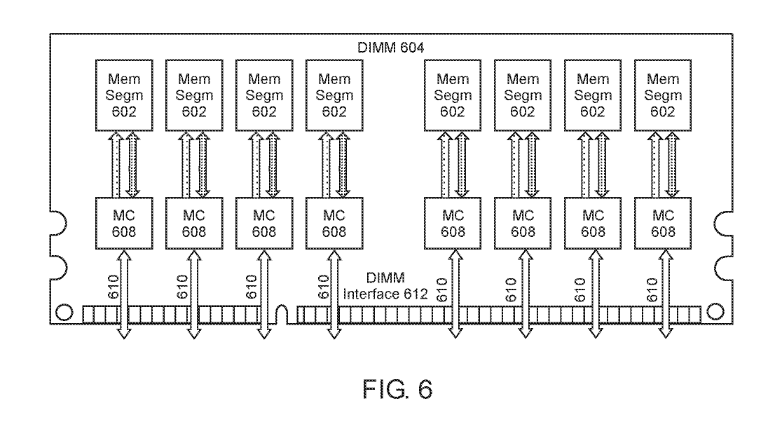

FIG. 6 shows one example of a memory module, such as a DIMM 604, having a plurality of memory segments 602 supported thereon. The DIMM 604 further includes one or more memory controllers 608, with each memory controller 608 communicating over independent memory channels with one or more memory segments 602. In the configuration shown in FIG. 6, each memory segment 602 is controlled by one dedicated memory controller 608 through an independent memory channel. In this case, each memory controller 608 can communicate through an independent channel 610 with a host via a discrete set of pins at the DIMM interface 612. Alternatively, all of the memory controllers on the DIMM can communicate with the host over a common channel through the DIMM interface. In this case, the host would send a memory access request over the common channel, and the appropriate memory controller would transact the requested memory operation through the independent memory channel with the associated memory segment.

In example embodiments with the system memory is supported on a memory module, such as a DIMM, the configuration of the data bus and the command bus can vary, depending on the type of memory, applicable standards in the art, system-specific configurations, and the like. For example, in the case of the DDRx SDRAM standards from the JEDEC outlined above, each specific DDRx standard can differ with respect to memory commands, memory command use, pinouts, and the like. As such, it should be understood that, while details provided herein may be specific to one standard, one of ordinary skill in the art can readily translate such details to another standard.

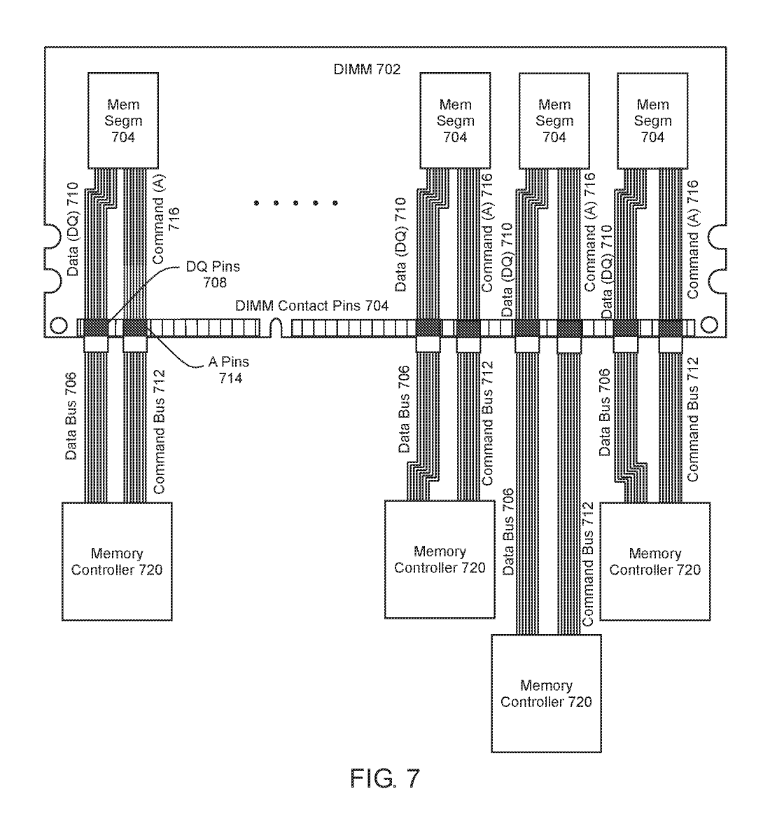

An example of a memory module is provided in FIG. 7. The memory module, which can be configured as a DIMM 702, supports a number of memory segments 704, which can vary in number and positioning depending on the type of memory segment, the memory controller configuration, the architecture of the DIMM, and the like. The DIMM 702 includes DIMM contact pins 704 that interface with corresponding contact pins of a DIMM connector (not shown) when inserted there into. The data bus 706 from a memory controller 720 comprises a plurality of independent data lines that interface with a corresponding plurality of data (DQ) pins 708 that are a subset of the DIMM contact pins 704. The DQ pins 708 communicatively couple with the associated memory segment 704 over a plurality of independent DQ lines 710. The number of DQ lines 710 depends on the architecture the memory segment 704. For example, if the memory segment is an x8 DDR, then eight DQ lines would be coupled to the memory segment. Furthermore, the command bus 712 from the memory controller 720 comprises a plurality of independent command lines that interfaces with a corresponding plurality of command (A, or CA) pin 714 from the DIMM contact pins 704. As with the DQ lines, the number of A or CA lines depends on the architecture of the memory segment 704. For example, LPDDR4 can use 6 CA lines per channel, and DDR4 can use 18 A lines per channel. The A pins 714 communicatively couple with the associated memory segment 704 over a plurality of independent A lines 716. As can be seen in FIG. 7, the command bus 712 provides command and address communications from the memory controller 722 to only one associated memory segment 704. As such, in response to a memory access request from a host, the memory controller 720 will only retrieve data from the associated memory segment 704.

In addition to the DQ and A pins, various other dedicated pins and associated lines can be configured as independent communication lines between the DIMM contact pins and a given memory segment. As such, an “independent pinout” describes a pinout configuration of only the pins associated with independent lines between the memory controller and the memory segment. Thus, for the example shown in FIG. 7, the independent pinout would include at least the DQ pins 708 and the A pins 714, including the associated DQ and A lines. Nonlimiting examples of potential independent pins and lines between a memory controller and a memory segment can include a dedicated chip select (CS) pin and a dedicated CS line, a dedicated clock enable (CKE) pin and a dedicated CKE line, a dedicated data strobe (DQS) pin and a dedicated DQS line, a dedicated activate command (ACT) pin and a dedicated ACT line, a dedicated clock (CK) pin and a dedicated CK line, a dedicated row access strobe (RAS) pin and a dedicated RAS line, a dedicated column access strobe (CAS) pin and a dedicated CAS line, and a dedicated write enable (WE) pin and a dedicated WE line, including multiples and combinations thereof. In one specific example, an independent pinout can include a plurality of DQ pins, a plurality of A pins, and at least one ACT pin, along with the associated DQ, A, and ACT lines. In another specific example, an independent pinout can include a plurality of DQ pins, a plurality of A pins, at least one CS pin, at least one CKE pin, and at least one DQS pin, along with the associated DQ, A, CS, CKE, and DQS lines. Thus, for each independent memory channel, including for each multiple independent line (e.g. multiple DQ lines), the independent pinout includes a dedicated pin to interface each independent line with the appropriate pin on the memory segment. In other examples, an independent pinout can include a plurality of DQ pins and pins associated with one or more command/address pins as an alternative to A or CA pins. For example, such alternative command/address pins can include RAS, CAS, WE, and the like, including multiples thereof.

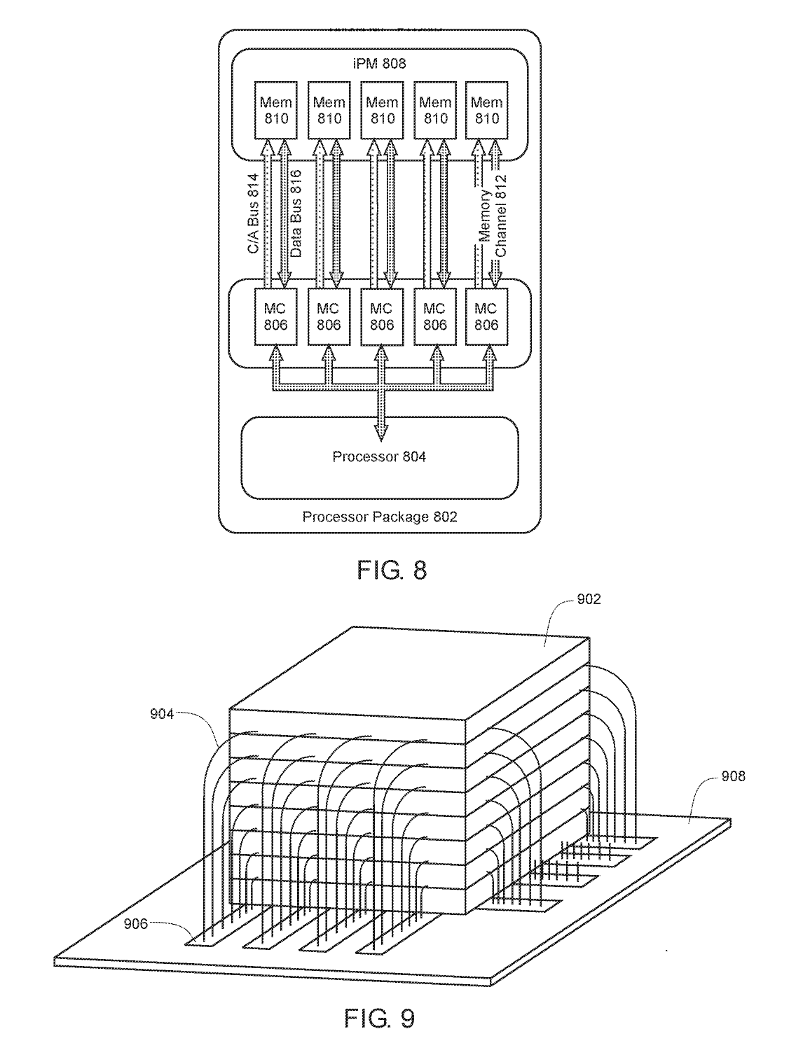

In other examples, in-package-memory (iPM) subsystems, package-on-package (PoP) subsystems, and the like, are provided, including devices and systems that support such subsystems. These subsystems can be incorporated into any type of compatible package architecture, including without limitation, processor packages in general, multi-core processor packages, multi-chip modules (MCMs), system-on-chip (SoC) packages, system-in-package (SiP), system-on-package (SOP), and the like. FIG. 8, for example, shows a processor package 802 that can be representative of any type of package. The package 802 includes one or more processors or processor cores (collectively “processor 804”), and at least one integrated memory controller 806 communicatively coupled to the processor 804. The processor package 802 includes an iPM 808, which is subdivided into a plurality of memory subsections 810, and a plurality of independent memory channels 812. Each memory channel 812 is communicatively coupled between the at least one integrated memory controller 806 and a single memory subsection 810. In some examples, the at least one memory controller 806 can be a plurality of memory controllers 806, where each memory controller 806 is dedicated to a single memory subsection 810 over a single memory channel 812, as is shown in FIG. 8. In other examples, as has been described herein, a single memory controller can communicatively couple to each memory segment independently through the associated memory channel, or the memory controller can be multiple memory controllers, where each memory controller communicatively couples to multiple memory segments in a similar fashion. Additionally, each memory channel 812 includes a dedicated command bus 814 (or command/address bus) communicatively coupled between the at least one integrated memory controller 806 and the associated memory subsection 810, and a dedicated data bus 816 communicatively coupled between the at least one integrated memory controller 806 and the associated memory subsection 810.

The memory subsections can be in a variety of nonlimiting configurations that are compatible with the associated package architecture. For example, in some cases each memory subsection can be an individual memory die, and in other cases each memory subsection can include multiple memory dies coupled together in a planar configuration. Regardless of the die-configuration, the memory subsections can be arranged in the package according to any desired or useful arrangement, and can be grouped in one package region or in multiple package regions. In one example, the memory subsections can be arranged on the package in a planar configuration, while in another example at least a portion of the memory subsections can be arranged on the package in a stacked configuration, or in other words, stacked upon one another. FIG. 9 shows an example of one possible architecture for a plurality of memory layers 902 in a stacked configuration. In some cases, each memory layer 902 can include a single memory subsection, while in other cases, each memory layer 902 can include multiple memory subsections. Additionally, each memory subsection can include a single die or multiple dies.

A plurality of wire-bonded contacts 904 communicatively couple each memory layer 902 to a plurality of communication channels 906 formed in the underlying substrate 908. The previously described independent memory channels are communicatively coupled to each memory segment, whether the memory segment is an entire memory layer 902 or a portion thereof. As such, in cases where multiple memory segments utilize the same communication channel 906, the independent nature of each memory segment's memory channel is maintained within the communication channel 906. Such a memory layer stack can be a stacked memory component of an iPM subsystem, a PoP subsystem, or the like. The stacked memory component can, in some examples, couple to one or more other stacked or planar memory components, and thus be packaged as multiple memory components, or in other words, be a part of a larger memory package. In other examples, the stacked memory component, either alone or with other stacked or planar memory components, can be coupled to a processor package, or to computation dies in a package.

Regardless of whether the system memory is on-package or off-package, the processor can include any processor type or configuration. A processor can be one processor, or multiple processors, including single core processors and multi-core processors. In some cases, the processor can be one or more central processing units (CPU). In other cases, a processor can be one or more field programmable gate arrays (FPGA), which can be utilized alone or in combination with another processor. A processor can be packaged in numerous configurations, which is not limiting. For example, a processor can be packaged in a common processor package, multi-core processor package, SoC package, SiP package, SOP package, and the like.

In one example, a computation system comprises at least one CPU, at least one FPGA communicatively coupled to the CPU, and at least one integrated memory controller communicatively coupled to the FPGA. The computation system can include an in-package system memory divided into a plurality of discrete memory subsections, and a plurality of independent memory channels, where each memory channel is communicatively coupled between the at least one integrated memory controller and a single memory subsection. The FPGA and the system memory can be integrated on-package with the CPU, or the FPGA and the system memory can be separately packaged together, and be communicatively coupled to the CPU.

In one example, a memory subsystem includes circuitry configured to address the system memory through the plurality of independent memory channels. Such circuitry can be processor circuitry, memory controller circuitry, memory management unit circuitry, or the like. The addressing can be incorporated into metadata, into memory address requests, or the like. For example, one or more bits on the address or command bus can be configured to indicate the memory subsection destination for the data/command. In one example, circuitry in a memory controller from a plurality of memory controllers can be configured to pick up memory access requests for the associated memory subsection using an address translation table. In another example, the circuitry can be processor circuitry, or circuitry located between the processor and a plurality of memory controllers. In such cases, the circuitry can function as an arbiter, and send memory access requests to the appropriate controllers, either through separate busses, or by manipulations to the memory access request address. In yet another example, the address space of the system memory map, memory management unit, and/or memory controller address tables can be configured to include such addressing information.

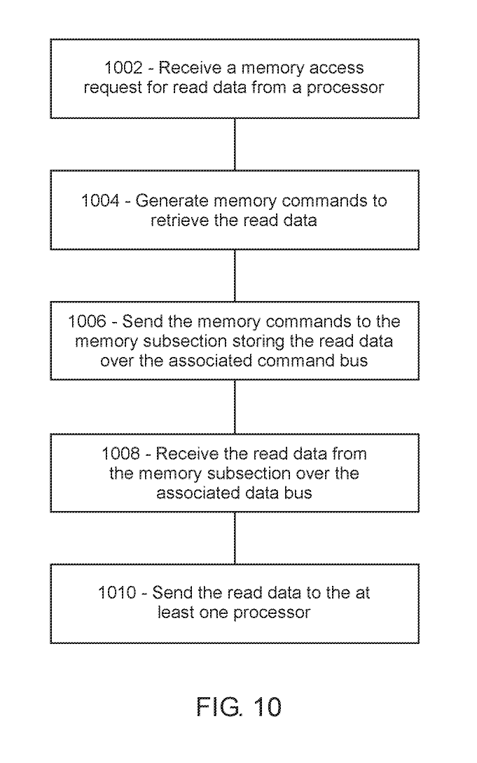

Additionally, various components of the present devices, systems, and subsystems, can comprise circuitry configured to negotiate memory access requests and associated data read and write operations over the various independent memory channels. For example, a memory controller can comprise circuitry, as shown in FIG. 10, that is configured to 1002 receive a memory access request for read data from a processor, 1004 generate memory commands to retrieve the read data, 1006 send the memory commands to the memory subsection storing the read data over the associated command bus through the associated independent memory channel, 1008 receive the read data from the memory subsection over the associated data bus through the associated independent memory channel, and 1010 send the read data to the processor to fill the memory access request.

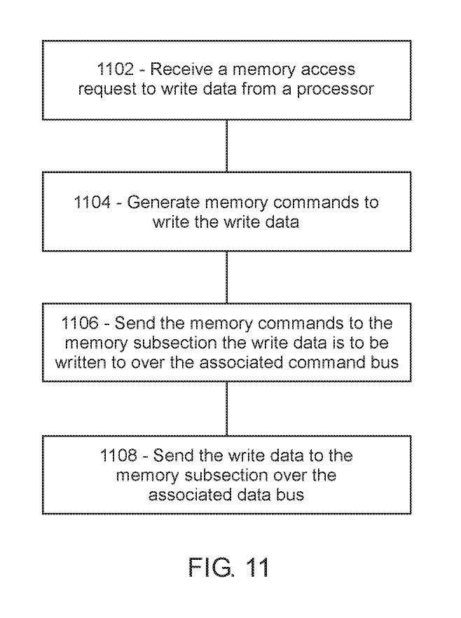

In another example, a memory controller can comprise circuitry, as shown in FIG. 11, that is configured to 1102 receive a memory access request to write data from a processor, 1104 generate memory commands to write the write data, 1106 send the memory commands to the memory subsection to which the write data is to be written over the associated command bus through the associated independent memory channel, and 1108 send the write data to the memory subsection to which the write data is to be written over the associated data bus through the associated independent memory channel.

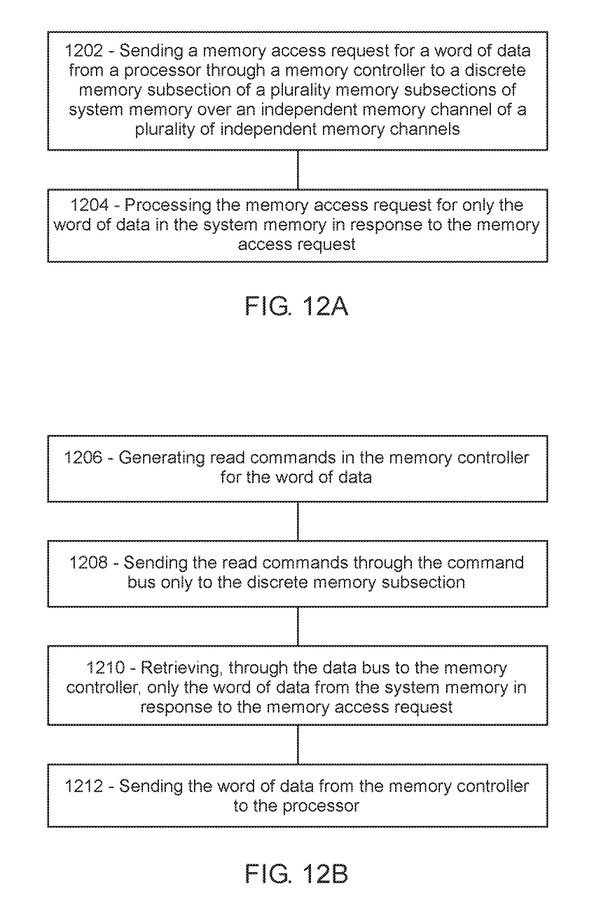

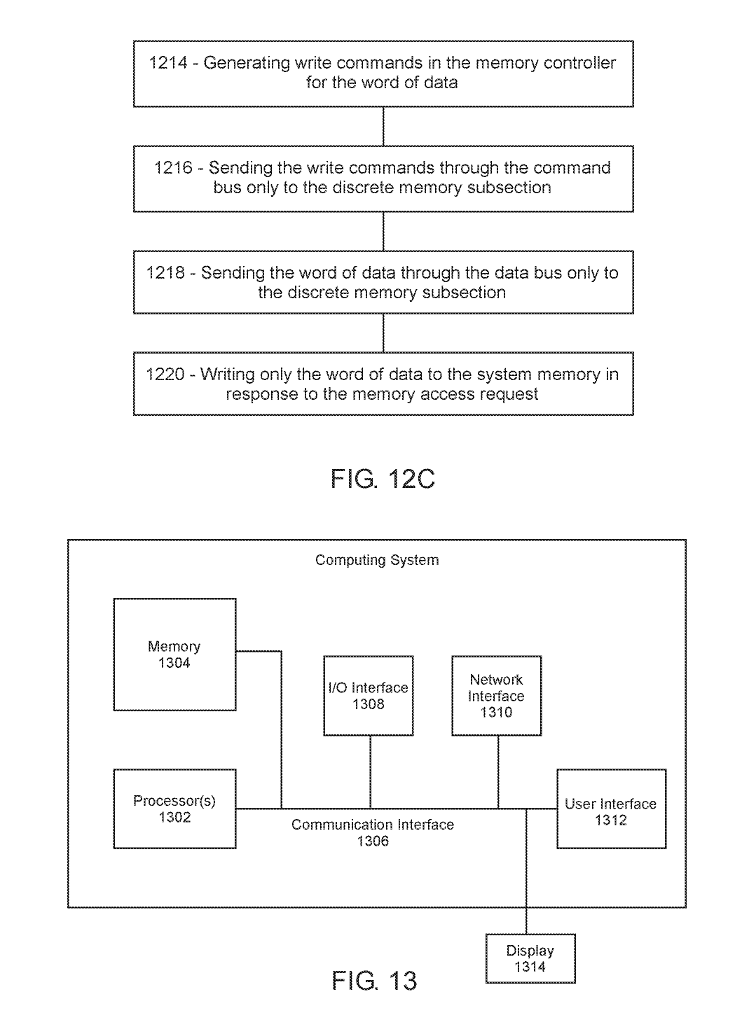

Additionally provided, in one example, is a method of reducing energy overhead and optimizing bandwidth for computational processing of data having low spatial locality. In one non-limiting implementation, as is shown in FIGS. 12A-C, such a method can include 1202 sending a memory access request for a word of data from a processor through a memory controller to a discrete memory subsection of a plurality memory subsections of system memory over an independent memory channel of a plurality of independent memory channels, and 1204 processing the memory access request for only the word of data in the system memory in response to the memory access request. Each independent memory channel comprises a dedicated command bus communicatively coupled between the memory controller and the memory subsection, and a dedicated data bus communicatively coupled between the memory controller and the memory subsection. FIG. 12B provides an example method where the memory access request is a read request for a word of data, and processing the memory access request further comprises 1206 generating read commands in the memory controller for the word of data, 1208 sending the read commands through the command bus only to the discrete memory subsection, 1210 retrieving, through the data bus to the memory controller, only the word of data from the system memory in response to the memory access request, and 1212 sending the word of data from the memory controller to the processor. FIG. 12C provides an example method where the memory access request is a write request for the word of data, and processing the memory access request further comprises 1214 generating write commands in the memory controller for the word of data, 1216 sending the write commands through the command bus only to the discrete memory subsection, 1218 sending the word of data through the data bus only to the discrete memory subsection, and 1220 writing only the word of data to the system memory in response to the memory access request.

As another example, FIG. 13 illustrates one embodiment of a general computing system that can incorporate the present technology. While any type or configuration of device or computing system is contemplated to be within the present scope, non-limiting examples can include node computing systems, SoC systems, SiP systems, SoP systems, server systems, networking systems, high capacity computing systems, laptop computers, tablet computers, desktop computers, smart phones, or the like.

The computing system can include one or more processors 1302 in communication with a memory 1304. The memory 1304 can include any device, combination of devices, circuitry, or the like, that is capable of storing, accessing, organizing, and/or retrieving data. Additionally, a communication interface 1306, such as a local communication interface, for example, provides connectivity between the various components of the system. The communication interface 1306 can vary widely depending on the processor, chipset, and memory architectures of the system. For example, the communication interface 1306 can be a local data bus, command/address buss, package interface, or the like.

The computing system can also include an I/O (input/output) interface 1308 for controlling the I/O functions of the system, as well as for I/O connectivity to devices outside of the computing system. A network interface 1310 can also be included for network connectivity. The network interface 1310 can control network communications both within the system and outside of the system, and can include a wired interface, a wireless interface, a Bluetooth interface, optical interface, communication fabric, and the like, including appropriate combinations thereof. Furthermore, the computing system can additionally include a user interface 1312, a display device 1314, as well as various other components that would be beneficial for such a system.

The processor 1302 can be a single or multiple processors, including single or multiple processor cores, and the memory can be a single or multiple memories. The local communication interface 1306 can be used as a pathway to facilitate communication between any of a single processor or processor cores, multiple processors or processor cores, a single memory, multiple memories, the various interfaces, and the like, in any useful combination. In some examples, the communication interface 1306 can be a separate interface between the processor 1302 and one or more other components of the system, such as, for example, the memory 1304. The memory 1304 can include system memory that is volatile, nonvolatile, or a combination thereof, as described herein. The memory 1304 can additionally include NVM utilized as a memory store.

Various techniques, or certain aspects or portions thereof, can take the form of program code (i.e., instructions) embodied in tangible media, such as floppy diskettes, CD-ROMs, hard drives, non-transitory computer readable storage medium, or any other machine-readable storage medium wherein, when the program code is loaded into and executed by a machine, such as a computer, the machine becomes an apparatus for practicing the various techniques. Circuitry can include hardware, firmware, program code, executable code, computer instructions, and/or software. A non-transitory computer readable storage medium can be a computer readable storage medium that does not include signal. In the case of program code execution on programmable computers, the computing device can include a processor, a storage medium readable by the processor (including volatile and non-volatile memory and/or storage elements), at least one input device, and at least one output device. The volatile and non-volatile memory and/or storage elements can be a RAM, EPROM, flash drive, optical drive, magnetic hard drive, solid state drive, or other medium for storing electronic data.

### EXAMPLES

The following examples pertain to specific embodiments and point out specific features, elements, or steps that can be used or otherwise combined in achieving such embodiments.

In one example, there is provided a memory subsystem comprising at least one memory controller, a system memory interface divided into a plurality of discrete interface subsections, the system memory interface configured to communicatively couple to a system memory divided into a corresponding plurality of memory subsections, and a plurality of independent memory channels communicatively coupled to the at least one memory controller. Each memory channel further comprises an interface subsection of the system memory interface configured to communicatively couple to one memory subsection of the system memory, a dedicated command bus communicatively coupled between the at least one memory controller and the interface subsection, and a dedicated data bus communicatively coupled between the at least one memory controller and the interface subsection.

In one example of a memory subsystem, the at least one memory controller is a plurality of dedicated memory controllers, where each of the plurality of independent memory channels is communicatively coupled to a dedicated memory controller.

In one example of a memory subsystem, the memory subsystem further comprising a system memory divided into a plurality of memory subsections, where each memory subsection is communicatively coupled to the interface subsection of one memory channel of the plurality of memory channels.

In one example of a memory subsystem, each of the plurality of memory subsections is a discrete division of dynamic random-access memory (DRAM).

In one example of a memory subsystem, each of the plurality of memory subsections is a discrete division of three-dimensional (3D) cross-point memory.

In one example of a memory subsystem, each of the plurality of memory subsections is a memory chip.

In one example of a memory subsystem, the plurality of memory subsections is coupled to a memory card, and each interface subsection is a discrete portion of a memory card connector.

In one example of a memory subsystem, the plurality of memory subsections is coupled to a dual in-line memory module (DIMM), and each interface subsection is a discrete portion of a DIMM connector.

In one example of a memory subsystem, the at least one memory controller is directly coupled to the memory card.

In one example of a memory subsystem, the at least one memory controller, the plurality of memory channels, and the plurality of memory subsections, are on a common package.

In one example of a memory subsystem, the memory subsections are in a stacked configuration.

In one example of a memory subsystem, each memory subsection comprises multiple memory dies in a planar configuration.

In one example of a memory subsystem, the memory subsections are in a stacked configuration.

In one example of a memory subsystem, the common package further comprises at least one processor.

In one example of a memory subsystem, the at least one processor comprises a member selected from the group consisting of central processing units (CPUs), multi-core CPUs, processors, multi-core processors, field programmable gate arrays (FPGA), and combinations thereof.

In one example of a memory subsystem, the at least one processor is at least one CPU or CPU core, and the common package further comprises an FPGA.

In one example of a memory subsystem, each memory channel is configured to be disabled independently from each of the other memory channels.

In one example of a memory subsystem, at least two of the plurality of independent memory channels share a common memory controller.

In one example, there is provided a computational system, comprising at least one processor, at least one memory controller, a system memory interface divided into a plurality of discrete interface subsections, and configured to communicatively couple to a system memory divided into a corresponding plurality of memory subsections, and a plurality of independent memory channels communicatively coupled to the at least one memory controller. Each memory channel further comprises an interface subsection of the system memory interface configured to communicatively couple to one memory subsection of the system memory, a dedicated command bus communicatively coupled between the at least one memory controller and the interface subsection, and a dedicated data bus communicatively coupled between the at least one memory controller and the interface subsection.

In one example of a system, the at least one memory controller is a plurality of dedicated memory controllers, where each of the plurality of independent memory channels is communicatively coupled to a dedicated memory controller.

In one example of a system, the system further comprises a system memory divided into a plurality of memory subsections, where each memory subsection is communicatively coupled to the system memory interface of one memory channel of the plurality of memory channels.

In one example of a system, each of the plurality of memory subsections is a discrete division of a dynamic random-access memory (DRAM).

In one example of a system, each of the plurality of memory subsections is a discrete division of a three-dimensional (3D) cross-point memory.

In one example of a system, each of the plurality of memory subsections is a memory chip.

In one example of a system, the plurality of memory subsections is coupled to a memory card, and each interface subsection is a discrete portion of a memory card connector.

In one example of a system, the plurality of memory subsections is coupled to a dual in-line memory module (DIMM), and each interface subsection is a discrete portion of a DIMM connector.

In one example of a system, the at least one memory controller is directly coupled to the memory card.

In one example of a system, the at least one memory controller, the plurality of memory channels, and the plurality of memory subsections, are on a common package.

In one example of a system, the memory subsections are in a stacked configuration.

In one example of a system, each memory subsection comprises multiple memory dies coupled together in a planar configuration.

In one example of a system, the memory subsections are in a stacked configuration.

In one example of a system, the common package die further comprises the at least one processor.

In one example of a system, the at least one processor comprises a member selected from the group consisting of central processing units (CPU), multi-core CPUs, field programmable gate arrays (FPGA), and combinations thereof.

In one example of a system, the at least one processor is at least one CPU or CPU core, and the common package further comprises and FPGA.

In one example of a system, the at least one memory controller further comprises circuitry configured to receive a memory access request for read data from the at least one processor, generate memory commands to retrieve the read data, send the memory commands to the memory subsection storing the read data over the associated command bus, receive the read data from the memory subsection over the associated data bus, and send the read data to the at least one processor.

In one example of a system, the at least one memory controller further comprises circuitry configured to receive a memory access request for write data from the at least one processor, generate memory commands to write the write data, send the memory commands to the memory subsection to which the write data is to be written over the associated command bus, and send the write data to the memory subsection to which the write data is to be written over the associated data bus.

In one example of a system, the data access granularity of each independent memory channel is a product of the data bus bit-width and the data bus burst length.

In one example of a system, the data access granularity of each independent memory channel is a multiple of 8 Bytes.

In one example of a system, the data access granularity of each independent memory channel is 8 Bytes.

In one example of a system, each memory channel is configured to be disabled independently from each of the other memory channels.

In one example of a system, at least two of the plurality of independent memory channels share a common memory controller.

In one example, there is provided a computation system comprising at least one central processing unit (CPU), at least one field programmable gate arrays (FPGA) communicatively coupled to the CPU, at least one integrated memory controller communicatively coupled to the FPGA, an in-package system memory divided into a plurality of discrete memory subsections, and a plurality of independent memory channels, each memory channel communicatively coupled between the at least one integrated memory controller and a single memory subsection. Each memory channel further comprises a dedicated command bus communicatively coupled between the at least one integrated memory controller and the memory subsection, and a dedicated data bus communicatively coupled between the at least one integrated memory controller and the memory subsection.

In one example of a system, the at least one integrated memory controller is a plurality of dedicated memory controllers, where each of the plurality of independent memory channels is communicatively coupled to a dedicated memory controller.

In one example of a system, each of the plurality of memory subsections is a discrete division of dynamic random-access memory (DRAM).

In one example of a system, each of the plurality of memory subsections is a discrete division of three-dimensional (3D) cross-point memory.

In one example of a system, the FPGA, the at least one integrated memory controller, the plurality of memory channels, and the plurality of memory subsections, are on a common package.

In one example of a system, the at least one CPU is on the common package.

In one example of a system, the memory subsections are in a stacked configuration.

In one example, there is provided a memory apparatus, comprising a dual in-line memory module (DIMM), further comprising a plurality of memory chips coupled to the DIMM, and a plurality of independent memory channels, where each memory chip is communicatively coupled to a single memory channel. Each memory channel comprises an independent pinout of contact pins of the DIMM that is unique to the associated memory chip, further comprising a plurality of data (DQ) pins communicatively coupled to the memory chip over a plurality of dedicated DQ lines, and a plurality of dedicated address (A) pins communicatively coupled to the memory chip over a plurality of dedicated A lines, the DQ and A pins being configured to communicatively couple to at least one memory controller.

In one example of an apparatus, each independent pinout further comprises a pin selected from the group consisting of a dedicated chip select (CS) pin communicatively coupled to the memory chip over a dedicated CS line, a dedicated clock enable (CKE) pin communicatively coupled to the memory chip over a dedicated CKE line, a dedicated data strobe (DQS) pin communicatively coupled to the memory chip over a dedicated DQS line, a dedicated activate command (ACT) pin communicatively coupled to the memory chip over a dedicated ACT line, a dedicated clock (CK) pin communicatively coupled to the memory chip over a dedicated CK line, a dedicated row access strobe (RAS) pin communicatively coupled to the memory chip over a dedicated RAS line, a dedicated column access strobe (CAS) pin communicatively coupled to the memory chip over a dedicated CAS line, and a dedicated write enable (WE) pin communicatively coupled to the memory chip over a dedicated WE line, including multiples and combinations thereof.

In one example of an apparatus, each independent pinout further comprises a dedicated activate command (ACT) pin communicatively coupled to the memory chip over a dedicated ACT line.

In one example of an apparatus, each independent pinout further comprises a dedicated chip select (CS) pin communicatively coupled to the memory chip over a dedicated CS line, a dedicated clock enable (CKE) pin communicatively coupled to the memory chip over a dedicated CKE line, and a dedicated data strobe (DQS) pin communicatively coupled to the memory chip over a dedicated DQS line.

In one example of an apparatus, each of the plurality of memory chips is a dynamic random-access memory (DRAM) chip.

In one example of an apparatus, each of the plurality of memory chips three-dimensional (3D) cross-point memory chip.

In one example of an apparatus, the DIMM is a hybrid DIMM, and the plurality of memory chips comprises at last a plurality of dynamic random-access memory (DRAM) chips and a plurality of three-dimensional (3D) cross-point memory chips.

In one example, there is provided a system-in-package device (SiP), comprising a processor package, further comprising at least one processor, at least one integrated memory controller, a plurality of memory subsections of a system memory, and a plurality of independent memory channels, each memory channel communicatively coupled between the at least one integrated memory controller and a single memory subsection. Each memory channel further comprises a dedicated command bus communicatively coupled between the at least one integrated memory controller and the memory subsection, and a dedicated data bus communicatively coupled between at least one integrated memory controller and the memory subsection.

In one example of a device, the at least one integrated memory controller is a plurality of dedicated memory controllers, where each of the plurality of independent memory channels is communicatively coupled to a dedicated memory controller.

In one example of a device, each of the plurality of memory subsections is a discrete division of a dynamic random-access memory (DRAM).

In one example of a device, each of the plurality of memory subsections is a discrete division of a three-dimensional (3D) cross-point memory.

In one example of a device, the memory subsections are in a stacked configuration.

In one example of a device, each memory subsection comprises multiple memory dies coupled together in a planar configuration.

In one example of a device, the memory subsections are in a stacked configuration.

In one example of a device, the at least one processor comprises a member selected from the group consisting of central processing units (CPU), multi-core CPUs, field programmable gate arrays (FPGA), and combinations thereof.

In one example of a device, the at least one processor is at least one CPU or CPU core, and the processor package further comprises an FPGA.

In one example of a device, the at least one integrated memory controller further comprises circuitry configured to receive a memory access request for read data from the at least one processor, generate memory commands to retrieve the read data, send the memory commands to the memory subsection storing the read data over the associated command bus, receive the read data from the memory subsection over the associated data bus, and send the read data to the at least one processor.

In one example of a device, the at least one integrated memory controller further comprises circuitry configured to receive a memory access request for write data from the at least one processor, generate memory commands to write the write data, send the memory commands to the memory subsection to which the write data is to be written over the associated command bus, and send the write data to the memory subsection to which the write data is to be written over the associated data bus.

In one example of a device, the data access granularity of each independent memory channel is a product of the data bus bit-width and the data bus burst length.

In one example of a device, the data access granularity of each independent memory channel is a multiple of 8 Bytes.

In one example of a device, the data access granularity of each independent memory channel is 8 Bytes.

In one example of a device, each independent memory channel is configured to be disabled independently from each of the other independent memory channels.

In one example of a device, at least two of the plurality of independent memory channels share a common integrated memory controller.

In one example, there is provided a method of reducing energy and bandwidth overheads in computational processing of data having low spatial locality, comprising sending a memory access request for a word of data from a processor through a memory controller to a discrete memory subsection of a plurality memory subsections of system memory over an independent memory channel of a plurality of independent memory channels, wherein each memory channel comprises a dedicated command bus communicatively coupled between the memory controller and the memory subsection, and a dedicated data bus communicatively coupled between the memory controller and the memory subsection, and processing the memory access request for only the word of data in the system memory in response to the memory access request.

In one example of a method, the memory access request is a read request for the word of data, and processing the memory access request further comprises generating read commands in the memory controller for the word of data, sending the read commands through the command bus only to the memory subsection, retrieving, through the data bus to the memory controller, only the word of data from the system memory in response to the memory access request, and sending the word of data from the memory controller to the processor.

In one example of a method, the memory access request is a write request for the word of data, and processing the memory access request further comprises generating write commands in the memory controller for the word of data, sending the write commands through the command bus only to the memory subsection, sending the word of data through the data bus only to the memory subsection, and writing only the word of data to the system memory in response to the memory access request.

In one example of a method, each of the plurality of memory subsections is a discrete division of a dynamic random-access memory (DRAM).

In one example of a method, each of the plurality of memory subsections is a discrete division of a three-dimensional (3D) cross-point memory.

In one example of a method, each of the plurality of memory subsections is a memory chip.

In one example of a method, the plurality of memory subsections is coupled to a memory card.

In one example of a method, the plurality of memory subsections is coupled to a dual in-line memory module (DIMM).

In one example of a method, the plurality of memory subsections is in-package memory.

1. A memory subsystem, comprising:
at least one memory controller;
a system memory interface divided into a plurality of discrete interface subsections, and configured to communicatively couple to a system memory divided into a corresponding plurality of memory subsections; and
a plurality of independent memory channels communicatively coupled to the at least one memory controller, each memory channel further comprising:
an interface subsection of the system memory interface configured to communicatively couple to one memory subsection of the system memory;
a dedicated command bus communicatively coupled between the at least one memory controller and the interface subsection; and
a dedicated data bus communicatively coupled between the at least one memory controller and the interface subsection.

2. The memory subsystem of claim 1, wherein the at least one memory controller is a plurality of dedicated memory controllers, where each of the plurality of independent memory channels is communicatively coupled to a dedicated memory controller.

3. The subsystem of claim 1, further comprising a system memory divided into a plurality of memory subsections, where each memory subsection is communicatively coupled to the interface subsection of one memory channel of the plurality of memory channels.

4. The subsystem of claim 3, wherein each of the plurality of memory subsections is a discrete division of dynamic random-access memory (DRAM) or a discrete division of three-dimensional (3D) cross-point memory.

5. The subsystem of claim 3, wherein the plurality of memory subsections is coupled to a memory card, and each interface subsection is a discrete portion of a memory card connector.

6. The subsystem of claim 3, wherein the plurality of memory subsections is coupled to a dual in-line memory module (DIMM), and each interface subsection is a discrete portion of a DIMM connector.

7. The subsystem of claim 3, wherein the at least one memory controller, the plurality of memory channels, and the plurality of memory subsections, are on a common package.

8. The subsystem of claim 7, wherein the memory subsections are in a stacked configuration.

9. The subsystem of claim 7, wherein each memory subsection comprises multiple memory dies in a planar configuration.

10. The subsystem of claim 9, wherein the memory subsections are in a stacked configuration.

11. The subsystem of claim 7, wherein the common package further comprises at least one processor comprising a member selected from the group consisting of central processing units (CPUs), multi-core CPUs, processors, multi-core processors, field programmable gate arrays (FPGA), and combinations thereof.

12. The subsystem of claim 11, wherein the at least one processor is at least one CPU or CPU core, and the common package further comprises an FPGA.

13. The subsystem of claim 1, wherein each memory channel is configured to be disabled independently from each of the other memory channels.

14. The subsystem of claim 1, wherein at least two of the plurality of independent memory channels share a common memory controller.

15. The subsystem of claim 1, wherein the at least one memory controller further comprises circuitry configured to:
receive a memory access request for read data from the at least one processor;
generate memory commands to retrieve the read data;
send the memory commands to the memory subsection storing the read data over the associated command bus;
receive the read data from the memory subsection over the associated data bus; and
send the read data to the at least one processor; and
wherein the at least one memory controller further comprises circuitry configured to:
receive a memory access request for write data from the at least one processor;
generate memory commands to write the write data;
send the memory commands to the memory subsection to which the write data is to be written over the associated command bus; and
send the write data to the memory subsection to which the write data is to be written over the associated data bus.

16. The subsystem of claim 1, wherein the data access granularity of each independent memory channel is 8 bytes or a multiple of 8 Bytes.

17. A memory apparatus, comprising:
a dual in-line memory module (DIMM), further comprising:
a plurality of memory chips coupled to the DIMM; and
a plurality of independent memory channels, where each memory chip is communicatively coupled to a single memory channel, and each memory channel comprises:
an independent pinout of contact pins of the DIMM that is unique to the associated memory chip, further comprising a plurality of data (DQ) pins communicatively coupled to the memory chip over a plurality of dedicated DQ lines, and a plurality of dedicated address (A) pins communicatively coupled to the memory chip over a plurality of dedicated A lines, the DQ and A pins being configured to communicatively couple to at least one memory controller.

18. The apparatus of claim 17, wherein each independent pinout further comprises a pin selected from the group consisting of:
a dedicated chip select (CS) pin communicatively coupled to the memory chip over a dedicated CS line;
a dedicated clock enable (CKE) pin communicatively coupled to the memory chip over a dedicated CKE line;
a dedicated data strobe (DQS) pin communicatively coupled to the memory chip over a dedicated DQS line;
a dedicated activate command (ACT) pin communicatively coupled to the memory chip over a dedicated ACT line;
a dedicated clock (CK) pin communicatively coupled to the memory chip over a dedicated CK line;
a dedicated row access strobe (RAS) pin communicatively coupled to the memory chip over a dedicated RAS line;
a dedicated column access strobe (CAS) pin communicatively coupled to the memory chip over a dedicated CAS line; and
a dedicated write enable (WE) pin communicatively coupled to the memory chip over a dedicated WE line, including multiples and combinations thereof.

19. The apparatus of claim 17, wherein each independent pinout further comprises a dedicated activate command (ACT) pin communicatively coupled to the memory chip over a dedicated ACT line.

20. The apparatus of claim 17, wherein each independent pinout further comprises a dedicated chip select (CS) pin communicatively coupled to the memory chip over a dedicated CS line, a dedicated clock enable (CKE) pin communicatively coupled to the memory chip over a dedicated CKE line, and a dedicated data strobe (DQS) pin communicatively coupled to the memory chip over a dedicated DQS line.

21. The apparatus of claim 17, wherein each of the plurality of memory chips is a dynamic random-access memory (DRAM) chip or a three-dimensional (3D) cross-point memory chip.

22. The apparatus of claim 17, wherein the DIMM is a hybrid DIMM, and the plurality of memory chips comprises at last a plurality of dynamic random-access memory (DRAM) chips and a plurality of three-dimensional (3D) cross-point memory chips.

23. A method of reducing energy and bandwidth overheads in computational processing of data having low spatial locality, comprising:
sending a memory access request for a page of data from a processor through a memory controller to a discrete memory subsection of a plurality memory subsections of system memory over an independent memory channel of a plurality of independent memory channels, wherein each memory channel comprises:
a dedicated command bus communicatively coupled between the memory controller and the memory subsection; and
a dedicated data bus communicatively coupled between the memory controller and the memory subsection; and
processing the memory access request for only the page of data in the system memory in response to the memory access request.

24. The method of claim 23, wherein the memory access request is a read request for the page of data, and processing the memory access request further comprises:
generating read commands in the memory controller for the page of data;
sending the read commands through the command bus only to the memory subsection;
retrieving, through the data bus to the memory controller, only the page of data from the system memory in response to the memory access request; and
sending the page of data from the memory controller to the processor.

25. The method of claim 23, wherein the memory access request is a write request for the page of data, and processing the memory access request further comprises:
generating write commands in the memory controller for the page of data;
sending the write commands through the command bus only to the memory subsection;
sending the page of data through the data bus only to the memory subsection; and
writing only the page of data to the system memory in response to the memory access request.
